(19) United States
(12) Patent Application Publication
(10) Pub. No.: US 2009/0122272 A1
(43) Pub. Date: May 14, 2009

(54) PROJECTION APPARATUS USING SOLID-STATE LIGHT SOURCE ARRAY

(76) Inventors: Barry D. Silverstein, Rochester, NY (US); Robert Metzger, Fairport, NY (US); Joseph R. Bietry, Rochester, NY (US)

Correspondence Address: Frank Pincelli;Patent Legal Staff, Eastman Kodak Company, 343 State Street, Rochester, NY, 14650-2201, US

(21) Appl. No.: 11/937,729

(22) Filed: Nov. 9, 2007

(51) Int. Cl. G03B 21/20; G03B 21/14; G03B 21/00; G03B 21/28

(52) U.S. Cl. 353/81; 353/20; 353/33

(57) ABSTRACT

An illumination apparatus for a digital image projector, the illumination apparatus has a plurality of solid-state laser arrays, each laser array with one or more rows of laser. A light combiner has an output optical axis and a plurality of light-redirecting prisms arranged in a stack. Each light-redirecting prism has at least one contact surface that extends parallel to the output optical axis and is in optical contact with an adjacent prism in the stack and a light redirecting facet that is disposed at an oblique angle to the at least one contact surface.

### FIELD OF THE INVENTION

This invention generally relates to an apparatus for projecting a digital image and more particularly relates to an improved apparatus and method using solid-state array illumination for digital cinema projection.

### BACKGROUND OF THE INVENTION

In order to be considered as suitable replacements for conventional film projectors, digital projection systems must meet demanding requirements for image quality. This is particularly true for multicolor cinematic projection systems. Competitive digital projection alternatives to conventional cinematic-quality projectors must meet high standards of performance, providing high resolution, wide color gamut, high brightness, and frame-sequential contrast ratios exceeding 1,000:1.

The most promising solutions for multicolor digital cinema projection employ, as image forming devices, one of two basic types of spatial light modulators (SLMs). The first type of spatial light modulator is the Digital Light Processor (DLP), a digital micromirror device (DMD), developed by Texas Instruments, Inc., Dallas, Tex. DLP devices are described in a number of patents, for example U.S. Pat. No. 4,441,791; No. 5,535,047; No. 5,600,383; and U.S. Pat. No. 5,719,695. Optical designs for projection apparatus employing DLPs are disclosed in U.S. Pat. Nos. 5,914,818; 5,930,050; 6,008,951; and 6,089,717. DLPs have been successfully employed in digital projection systems.

FIG. 1 shows a simplified block diagram of a projector apparatus 10 that uses DLP spatial light modulators. A light source 12 provides polychromatic light into a prism assembly 14, such as a Philips prism, for example. Prism assembly 14 splits the polychromatic light into red, green, and blue component bands and directs each band to the corresponding spatial light modulator 20r, 20g, or 20b. Prism assembly 14 then recombines the modulated light from each SLM 20r, 20g, and 20b and provides this light to a projection lens 30 for projection onto a display screen or other suitable surface.

Although DLP-based projectors demonstrate capability to provide the necessary light throughput, contrast ratio, and color gamut for most projection applications from desktop to large cinema, there are inherent resolution limitations, with current devices providing only 2148×1080 pixels. In addition, high component and system costs have limited the suitability of DLP designs for higher-quality digital cinema projection. Moreover, the cost, size, weight, and complexity of the Philips or other suitable prisms as well as the fast projection lens with a long working distance required for brightness are inherent constraints with negative impact on acceptability and usability of these devices.

The second type of spatial light modulator used for digital projection is the LCD (Liquid Crystal Device). The LCD forms an image as an array of pixels by selectively modulating the polarization state of incident light for each corresponding pixel. LCDs appear to have advantages as spatial light modulators for high-quality digital cinema projection systems. These advantages include relatively large device size, favorable device yields and the ability to fabricate higher resolution devices, for example 4096×2160 resolution devices by Sony and JVC Corporations. Among examples of electronic projection apparatus that utilize LCD spatial light modulators are those disclosed in U.S. Pat. No. 5,808,795; U.S. Pat. No. 5,798,819; U.S. Pat. No. 5,918,961; U.S. Pat. No. 6,010,121; and U.S. Pat. No. 6,062,694. LCOS (Liquid Crystal On Silicon) devices are thought to be particularly promising for large-scale image projection. However, LCD components have difficulty maintaining the high quality demands of digital cinema, particularly with regard to color and contrast, as the high thermal load of high brightness projection affects the materials polarization qualities.

A continuing problem with illumination efficiency relates to etendue or, similarly, the Lagrange invariant. As is well known in the optical arts, etendue relates to the amount of light that can be handled by an optical system. Potentially, the larger the etendue, the brighter the image. Numerically, etendue is proportional to the product of two characteristics, namely the image area and the numerical aperture. In terms of the simplified optical system represented in FIG. 2 having light source 12, optics 18, and a spatial light modulator 20, etendue is a factor of the area of the light source A1 and its output angle θ1 and is equal to the area of the modulator A2 and its acceptance angle θ2. For increased brightness, it is desirable to provide as much light as possible from the area of light source 12. As a general principle, the optical design is advantaged when the etendue at the light source is most closely matched by the etendue at the modulator.

Increasing the numerical aperture, for example, increases etendue so that the optical system captures more light. Similarly, increasing the source image size, so that light originates over a larger area, increases etendue. In order to utilize an increased etendue on the illumination side, the etendue must be greater than or equal to that of the illumination source. Typically, however, the larger the image, the more costly and sizeable the optics and support components. This is especially true of devices such as LCOS and DLP components, where the silicon substrate and defect potential increase with size. As a general rule, increased etendue results in a more complex and costly optical design. Using an approach such as that outlined in U.S. Pat. No. 5,907,437 for example, lens components in the optical system must be designed for large etendue. The source image area for the light that must be converged through system optics is the sum of the combined areas of the spatial light modulators in red, green, and blue light paths; notably, this is three times the area of the final multicolor image formed. That is, for the configuration disclosed in U.S. Pat. No. 5,907,437, optical components handle a sizable image area, therefore a high etendue, since red, green, and blue color paths are separate and must be optically converged. Moreover, although a configuration such as that disclosed in U.S. Pat. No. 5,907,437 handles light from three times the area of the final multicolor image formed, this configuration does not afford any benefit of increased brightness, since each color path contains only one-third of the total light level.

Efficiency improves when the etendue of the light source is well-matched to the etendue of the spatial light modulator. Poorly matched etendue means that the optical system is either light-starved, unable to provide sufficient light to the spatial light modulators, or inefficient, effectively discarding a substantial portion of the light that is generated for modulation.

The goal of providing sufficient brightness for digital cinema applications at an acceptable system cost has eluded designers of both LCD and DLP systems. LCD-based systems have been compromised by the requirement for polarized light, reducing efficiency and increasing etendue, even where polarization recovery techniques are used. DLP device designs, not requiring polarized light, have proven to be somewhat more efficient, but still require expensive, short lived lamps and costly optical engines, making them too expensive to compete against conventional cinema projection equipment.

In order to compete with conventional high-end film-based projection systems and provide what has been termed electronic or digital cinema, digital projectors must be capable of achieving comparable cinema brightness levels to this earlier equipment. As some idea of scale, the typical theatre requires on the order of 10,000 lumens projected onto screen sizes on the order of 40 feet in diagonal. The range of screens requires anywhere from 5,000 lumens to upwards of 40,000 lumens. In addition to this demanding brightness requirement, these projectors must also deliver high resolution (2048×1080 pixels) and provide around 2000:1 contrast and a wide color gamut.

Some digital cinema projector designs have proved to be capable of this level of performance. However, high equipment and operational costs have been obstacles. Projection apparatus that meet these requirements typically cost in excess of $50,000 each and utilize high wattage Xenon arc lamps that need replacement at intervals between 500-2000 hours, with typical replacement cost often exceeding $1000. The large etendue of the Xenon lamp has considerable impact on cost and complexity, since it necessitates relatively fast optics to collect and project light from these sources.

One drawback common to both DLP and LCOS LCD spatial light modulators (SLM) has been their limited ability to use solid-state light sources, particularly laser sources. Although they are advantaged over other types of light sources with regard to relative spectral purity and potentially high brightness levels, solid-state light sources require different approaches in order to use these advantages effectively. Conventional methods and devices for conditioning, redirecting, and combining light from color sources, used with earlier digital projector designs, can constrain how well laser array light sources are used.

Solid-state lasers promise improvements in etendue, longevity, and overall spectral and brightness stability but, until recently, have not been able to deliver visible light at sufficient levels and within the cost needed to fit the requirements for digital cinema. In a more recent development, VCSEL (Vertical Cavity Surface-Emitting Laser) laser arrays have been commercialized and show some promise as potential light sources. However, the combined light from as many as 9 individual arrays is needed in order to provide the necessary brightness for each color.

Examples of projection apparatus using laser arrays include the following:

U.S. Pat. No. 5,704,700 describes the use of a microlaser array for projector illumination;

Commonly assigned U.S. Pat. No. 6,950,454 describes the use of organic lasers for providing laser illumination to a spatial light modulator;

U.S. Patent Application Publication No. 2006/0023173 describes the use of arrays of extended cavity surface-emitting semiconductor lasers for illumination; and

U.S. Pat. No. 7,052,145 describes different display embodiments that employ arrays of microlasers for projector illumination.

U.S. Pat. No. 6,240,116 discusses the packaging of conventional laser bar- and edge-emitting diodes with high cooling efficiency and describes using lenses combined with reflectors to reduce the divergence-size product (etendue) of a 2 dimensional array by eliminating or reducing the spacing between collimated beams.

There are difficulties with each of these types of solutions. Kappel '700 teaches the use of a monolithic array of coherent lasers for use as the light source in image projection, whereby the number of lasers is selected to match the power requirements of the lumen output of the projector. In a high lumen projector, however, this approach presents a number of difficulties. Manufacturing yields drop as the number of devices increases and heat problems can be significant with larger scale arrays. Coherence can also create problems for monolithic designs. Coherence of the laser sources typically causes artifacts such as optical interference and speckle. It is, therefore, preferable to use an array of lasers where coherence, spatial and temporal coherence is weak or broken. While a spectral coherence is desired from the standpoint of improved color gamut, a small amount of broadening of the spectrum is also desirable for removing the sensitivity to interference and speckle and also lessens the effects of color shift of a single spectral source. This shift could occur, for example, in a three color projection system that has separate red, green and blue laser sources. If all lasers in the single color arrays are tied together and of a narrow wavelength and a shift occurs in the operating wavelength, the white point and color of the entire projector may fall out of specification. On the other hand, where the array is averaged with small variations in the wavelengths, the sensitivity to single color shifts in the overall output is greatly reduced. While components may be added to the system to help break this coherence as discussed by Kappel, it is preferred from a cost and simplicity standpoint to utilize slightly varying devices from differing manufactured lots to form a substantially incoherent laser source. Additionally reducing the spatial and temporal coherence at the source is preferred, as most means of reducing this incoherence beyond the source utilizes components such as diffusers, which increase the effective extent of the source (etendue), cause additional light loss, and add expense to the system. Maintaining the small etendue of the lasers enable a simplification of the optical train, which is highly desired.

Laser arrays of particular interest for projection applications are various types of VCSEL (Vertical Cavity Surface-Emitting Laser) arrays, including VECSEL (Vertical Extended Cavity Surface-Emitting Laser) and NECSEL (Novalux Extended Cavity Surface-Emitting Laser) devices from Novalux, Sunnyvale, Calif. However, conventional solutions using these devices are prone to a number of problems. One limitation relates to device yields. Due largely to heat and packaging problems for critical components, the commercialized VECSEL array is extended in length, but limited in height; typically, a VECSEL array has only two rows of emitting components. The use of more than two rows tends to dramatically increase yield difficulties. This practical limitation would make it difficult to provide a VECSEL illumination system for projection apparatus as described in the Glenn '145 disclosure, for example. Brightness would be constrained when using the projection solutions proposed in the Mooradian et al. '3173 disclosure. Although Kruschwitz et al '454 and others describe the use of laser arrays using organic VCSELs, these organic lasers have not yet been successfully commercialized. In addition to these problems, conventional VECSEL designs are prone to difficulties with power connection and heat sinking. These lasers are of high power; for example, a single row laser device, frequency doubled into a two row device from Novalux produces over 3 W of usable light. Thus, there can be significant current requirements and heat load from the unused current. Lifetime and beam quality is highly dependent upon stable temperature maintenance.

Coupling of the laser sources to the projection system presents another difficulty that is not adequately addressed using conventional approaches. For example, using Novalux NESEL lasers, approximately nine 2 row by 24 laser arrays are required for each color in order to approximate the 10,000 lumen requirement of most theatres. It is desirable to separate these sources, as well as the electronic delivery and connection and the associated heat from the main thermally sensitive optical system to allow optimal performance of the projection engine. Other laser sources are possible, such as conventional edge emitting laser diodes. However, these are more difficult to package in array form and traditionally have a shorter lifetime at higher brightness levels.

None of the solutions yet proposed have addressed the problem of etendue-matching of the laser sources to the system, thermally separating the illumination sources from the optical engine. Nor have these solutions adequately addressed the need to use polarized light from the laser devices more effectively.

Thus, it can be seen that there is a need for illumination solutions that capitalize on the advantages of solid-state array light sources and allow effective use of solid-state illumination components with DLP and LCOS modulators.

### SUMMARY OF THE INVENTION

It is an object of the present invention to address the need for improved illumination apparatus used with digital spatial light modulators such as DLP and LCOS and related microdisplay spatial light modulator devices. With this object in mind, the present invention provides an illumination apparatus for a digital image projector, the illumination apparatus comprising: a plurality of solid-state laser arrays, each laser array comprising one or more rows of lasers; and a light combiner having an output optical axis and comprising a plurality of light-redirecting prisms arranged in a stack, each light-redirecting prism comprising: at least one contact surface that extends parallel or substantially parallel to the output optical axis and is in optical contact with an adjacent prism in the stack; and a light redirecting facet that is disposed at an oblique angle to the at least one contact surface.

It is a feature of the present invention that it provides ways to improve etendue matching between illumination and modulation components.

These and other objects, features, and advantages of the present invention will become apparent to those skilled in the art upon a reading of the following detailed description when taken in conjunction with the drawings wherein there is shown and described an illustrative embodiment of the invention.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1 is a schematic block diagram of a conventional projection apparatus using a combining prism for the different color light paths;

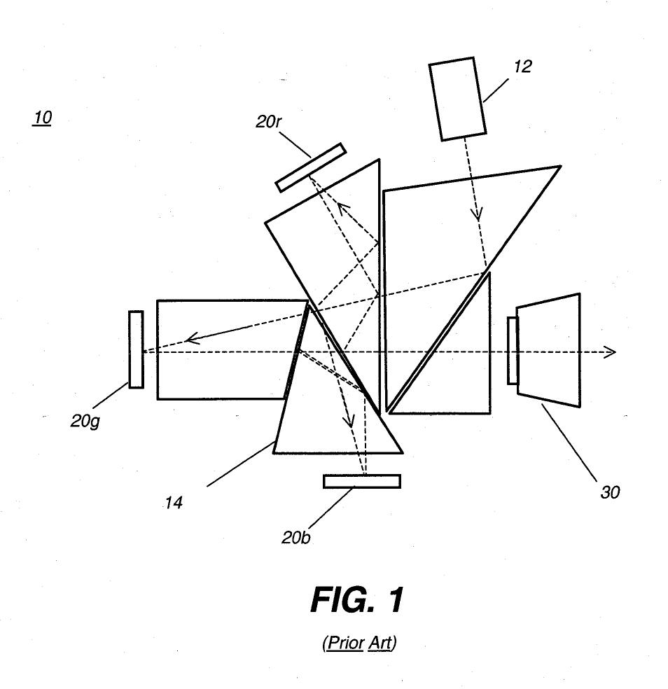

FIG. 2 is a representative diagram showing etendue for an optical system;

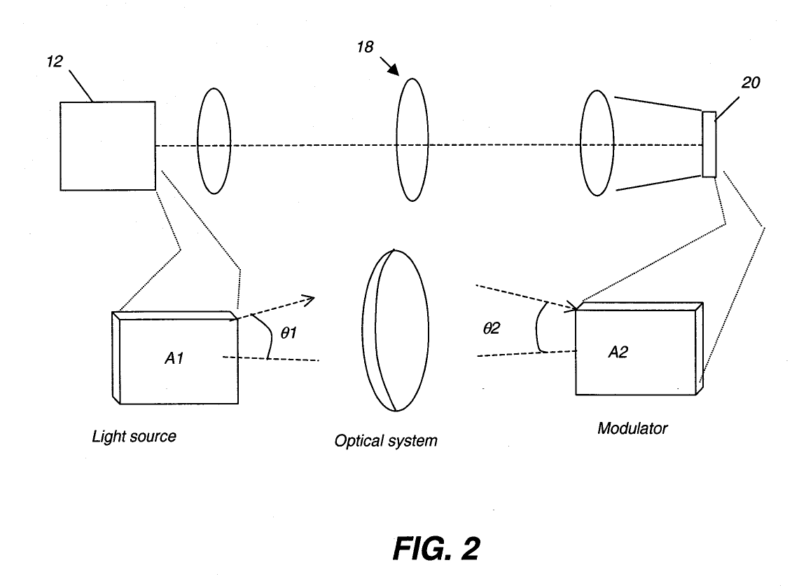

FIGS. 3A, 3B, and 3C are plan views showing the relative fill factor of different solid-state light array-to-light guide combinations;

FIG. 4A is a schematic side-view diagram showing one method for combining light from multiple solid-state light arrays along the same illumination path;

FIG. 4B is a schematic side-view diagram showing an alternate method for combining light from multiple solid-state light arrays along the same illumination path;

FIG. 5 is a perspective view of the configuration for combining light shown in FIG. 4A;

FIG. 6 is a schematic block diagram showing the general arrangement of a projection apparatus using the illumination combiner of the present invention;

FIG. 7A is a schematic side-view diagram showing the use of a light-redirecting prism for combining illumination from multiple solid-state light arrays in one embodiment;

FIG. 7B is a perspective view showing the configuration of FIG. 7A;

FIG. 7C is a perspective exploded view of a segmented illumination combiner according to one embodiment;

FIG. 8 is a schematic side-view diagram showing the use of a light-redirecting prism for combining illumination from multiple solid-state light arrays in another embodiment;

FIG. 9 is a schematic side-view showing the use of an offset symmetric embodiment of a light-redirecting prism that accepts light from both sides;

FIG. 10 is a side view showing light-redirecting prisms arranged to form an offset symmetric illumination combiner;

FIG. 11 shows calculations that can be applied for obtaining parallel light output from a light-redirecting prism;

FIG. 12 shows aspect ratio comparisons for the output face of a light redirecting prism and the spatial light modulator in one embodiment; and

FIG. 13 shows aspect ratio matching using polarized illumination.

### DETAILED DESCRIPTION OF THE INVENTION

Figures shown and described herein are provided to illustrate principles of operation according to the present invention and are not drawn with intent to show actual size or scale. Because of the relative dimensions of the component parts for the laser array of the present invention, some exaggeration is necessary in order to emphasize basic structure, shape, and principles of operation.

The term “oblique” as used in the present disclosure has its conventional meaning, in which an angular relationship to a reference line or plane is not parallel or other integer multiple of 90 degrees. An oblique angle is thus either greater than or less than a right (90 degree) angle and is not parallel with respect to its reference.

Embodiments of the present invention address the need for improved brightness using solid-state arrays and provide solutions that can allow ease of removal and modular replacement of laser assemblies. Embodiments of the present invention also provide features that reduce thermal effects that might otherwise cause thermally induced stress birefringence in optical components that are used with LCOS projectors.

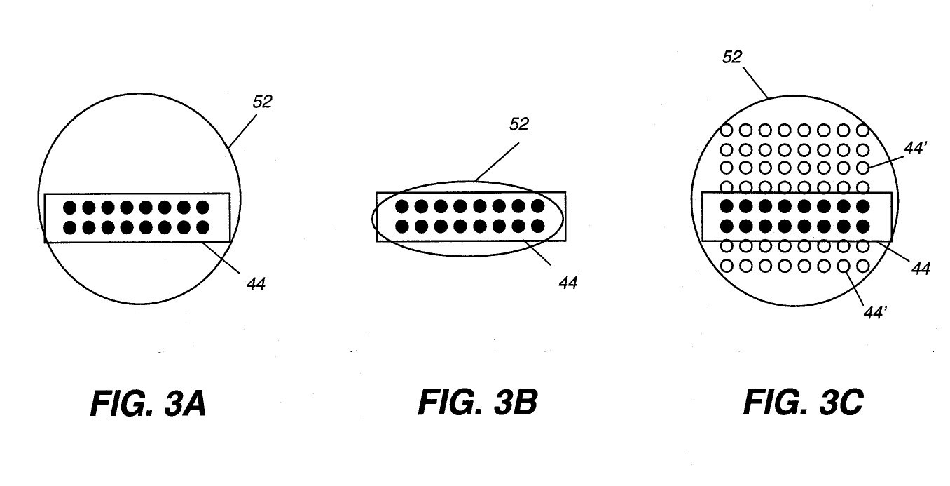

One approach used to reduce thermal loading by embodiments of the present invention is to isolate the light sources from light modulation components using a waveguide structure. Light from multiple solid-state light source arrays is coupled into optical waveguides that deliver the light to the modulation device. Moreover, the geometry of the light source-to-waveguide interface can be optimized so that the waveguide output is well matched to the aspect ratio of the spatial light modulator. In practice, this means that the waveguide aperture is substantially filled or slightly underfilled for maintaining optimal etendue levels. This arrangement also helps to minimize the speed requirement of illumination optics. Referring to FIGS. 3A, 3B, and 3C, the input aperture of a light guide 52 is shown in cross section. A solid-state light array 44 is shown as it would appear at the input aperture of light guide 52, properly scaled. As shown in FIG. 3A, the aperture is underfilled, which may easily cause a poor etendue match at the spatial light modulator end of light guide 52. In FIG. 3B, the aspect ratios of array 44 and light guide 52 are well matched by reshaping the input aperture of light guide 52 from its conventional circular form. FIG. 3C shows another arrangement in which multiple arrays 44′ are combined with array 44 to effectively form a larger array. Methods of combining multiple arrays 44 are described subsequently.

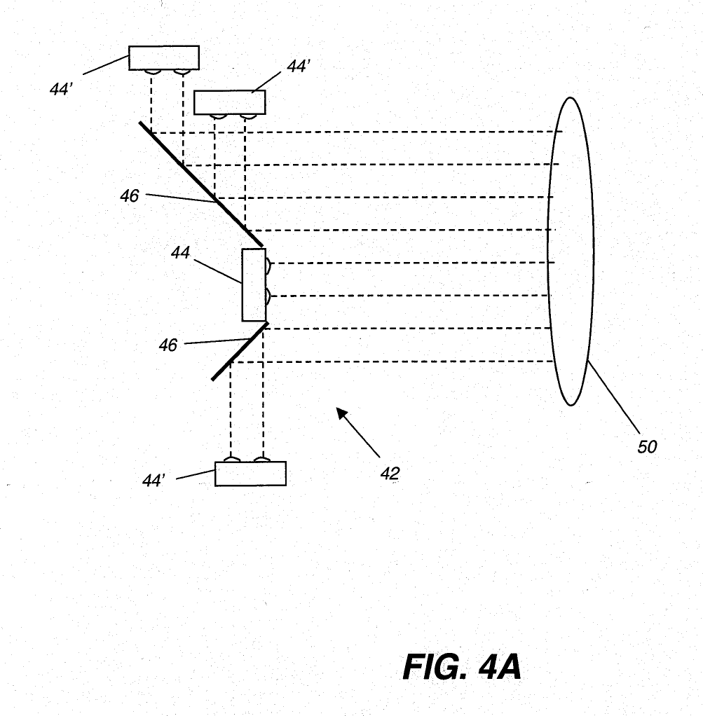

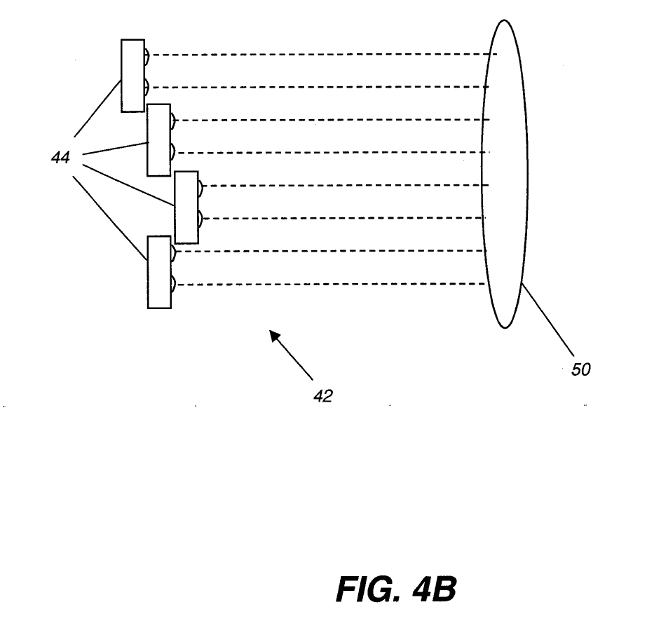

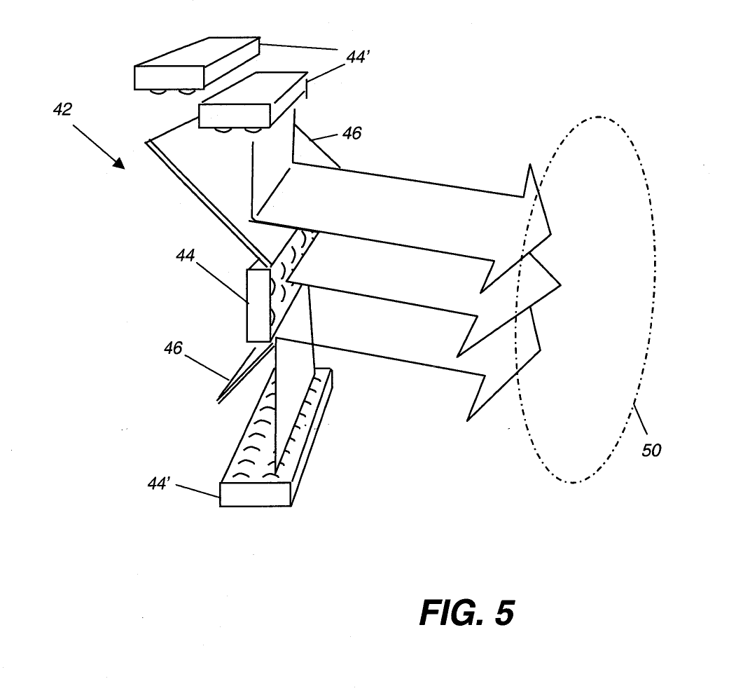

In embodiments using this approach, an optical fiber can be utilized for light guide 52. In one embodiment, a rectangular core optical fiber is used. For example, rectangular core fiber from Liekki of Lohaja, Finland has been fabricated to better match source aspect ratios. In this case, techniques such as taught by U.S. Pat. No. 6,240,116 to Lang et al. where stepped mirrors can be used, can shape the light from multiple arrays 44 to form a rectangular aspect ratio source with a smaller etendue. The approach shown in the Lang et al. '116 disclosure uses discrete diodes, whereby the vertical cavity lasers used in the preferred embodiment inherently have a low divergence angle and therefore do not require the use of a lens to collimate the beam. In an alternative approach, as shown in FIG. 4A and in perspective view in FIG. 5, one or more interspersed mirrors 46 may be used to place the optical axis of additional arrays 44′ in line with array 44 to provide the arrangement shown in cross-section in FIG. 3C. A more direct example using combined arrays 44 is shown in FIG. 4B. However, it can be appreciated that heat and spacing requirements may limit how many arrays 44 can be stacked in this manner.

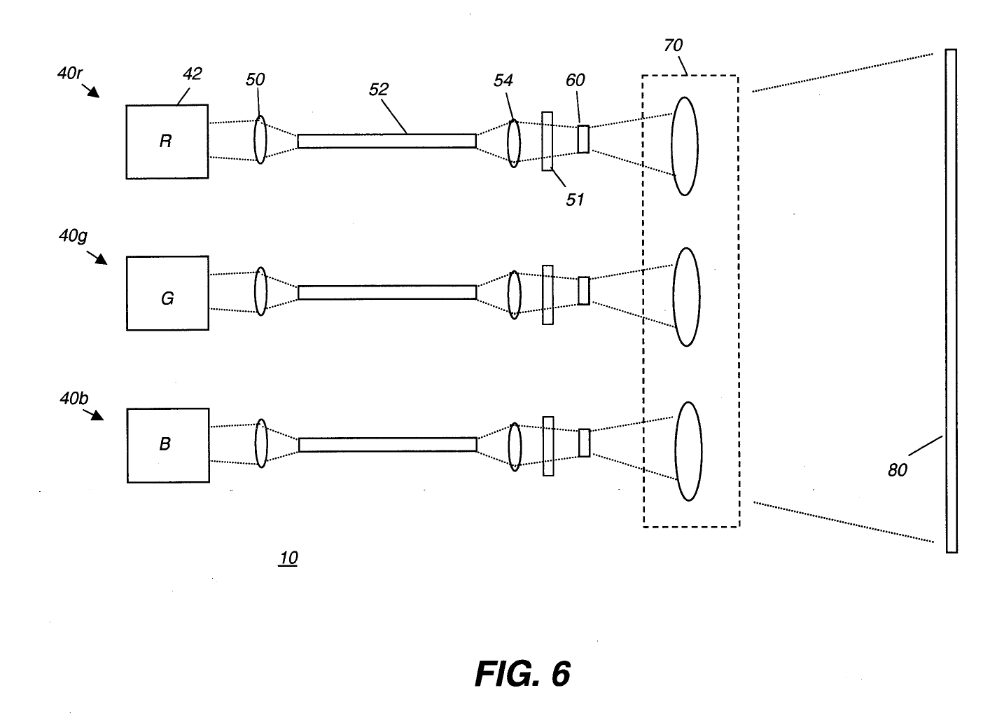

The schematic diagram of FIG. 6 shows a basic arrangement for projection apparatus 10 that is used in a number of embodiments of the present invention. Three light modulation assemblies 40r, 40g, and 40b are shown, each modulating one of the primary Red, Green, or Blue (RGB) colors from an illumination combiner apparatus 42. In each light modulation assembly 40r, 40g, and 40b, an optional lens 50 directs light into light guide 52, such as an optical fiber. At the output of light guide 52, a lens 54 directs light through an integrator 51, such as a fly's eye integrator or integrating bar, for example, to a spatial light modulator 60, which may be a DLP, LCOS, or other light modulating component. Projection optics 70, indicated generally in a dashed outline in FIG. 6 due to many possible embodiments, then direct the modulated light to a display surface 80. The basic arrangement shown in FIG. 6 is used for subsequent embodiments of the present invention, with various arrangements used for illumination combiner apparatus 42.

One problem of particular concern for large-scale projectors relates to the high brightness requirements and concomitant heat load that must be handled by the illumination optics. In order to take advantage of the low etendue, a typical digital cinema projector requiring 10,000 lumens would concentrate around 24 watts of power within approximately 4 square centimeters. When using solid-state laser arrays as the light source, the high heat levels such as these that may result can have significant effect on illumination combiner apparatus 42. Molded plastic assemblies, suitable for low-temperature operation, are limited to certain threshold heat levels; beyond these levels, birefringence, material damage, and other negative effects can result.

The limitations of optical plastics are a limitation even for high-end polymers having relatively high thermal characteristics. For example, one of the most durable optical plastics designed for molding is Zeonex, a cyclo-olefin polymer manufactured by Zeon Corporation, Louisville, Ky. This material has been shown to absorb about 2% of blue wavelength light between 420 nm and 450 nm, within the spectrum required to achieve appropriate color gamut for digital cinema applications. Additionally, this absorption increases by around 1% with as little a 2500 hours at room temperature and at a relatively small energy density of 400 mW per square centimeter. Yellowing can occur with this absorption level. As this example illustrates, molded plastics would be impractical for high-lumen illumination applications using solid-state laser arrays.

A molded glass assembly would be a possible alternative as a light combiner for high-lumen illumination applications. However, even when using high-temperature glasses and state-of-the-art glass molding technologies, fabrication of a suitable combiner device as a block of glass, considering the high heat stresses that are likely, may not be feasible.

Typical quality molded glass components range from aspheric lenses to lenslet arrays. Historically, Eastman Kodak Company, Rochester N.Y. has fabricated molded aspheric lenses up to 2″ diameter with relatively thin center thicknesses. Companies such as Docter Optics, Germany and Izuzu Glass, Japan have molded plates up to 2″ diagonals. In both cases the process begins with a glass perform that is heated and pressed between two surfaces. Since the materials do not start in a molten form, it is difficult to achieve even heating throughout, particularly with a thick component such as a prism. The need to heat the entire component can be minimized by using a more featured preform, whereby only the critical optical surfaces are molded. This technique, however, creates a potentially damaging differential stress between the outside of the prism and the inside. This stress can easily deteriorate the polarization properties of component. Therefore, molded glass prisms of this form are difficult to fabricate and do not perform as well as conventional bulk glass components.

The task of glass molding is constrained by the fact that only certain glass types have been found to mold effectively and in the difficulty of molding flats into glass. Glasses such as B270, for example, are commonly utilized for molding in order to achieve the consistent molding surface properties required by optical components. But other types of glass cannot be readily molded. This further limits the capability of forming a glass combiner that meets both the requirements of the molding process and the requirements of handling high light levels without compromising optical properties of the laser light.

For embodiments of the present invention, illumination combiner apparatus 42, used as a light redirector or light combiner, has a composite prism structure. Illumination combiner apparatus 42 is formed in segmented fashion from multiple prisms that are stacked together, each in optical contact with its neighbor along at least one surface. Components of illumination apparatus 42 include the light sources, provided by solid-state laser arrays, and the light combiner that is provided by a composite prism structure.

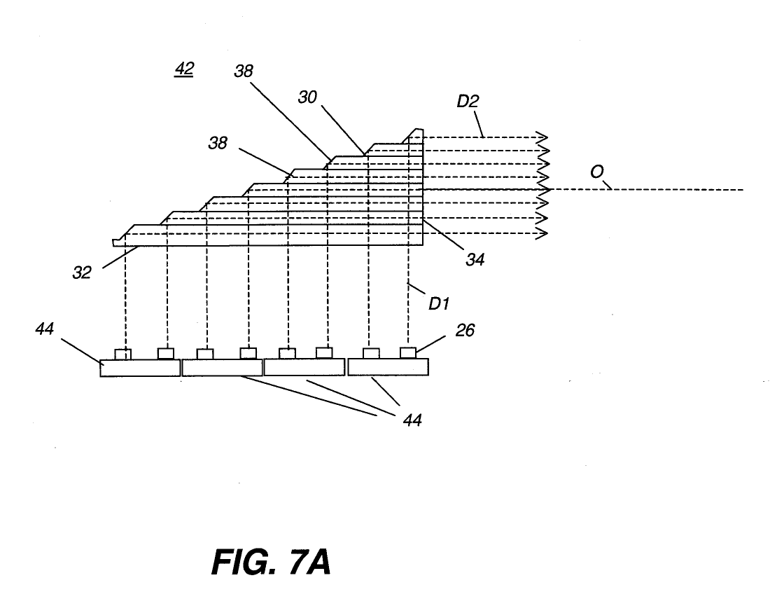

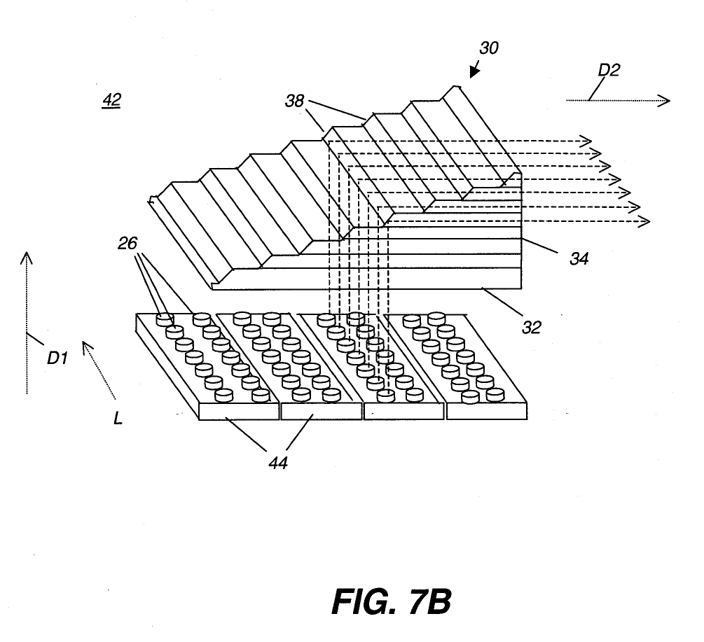

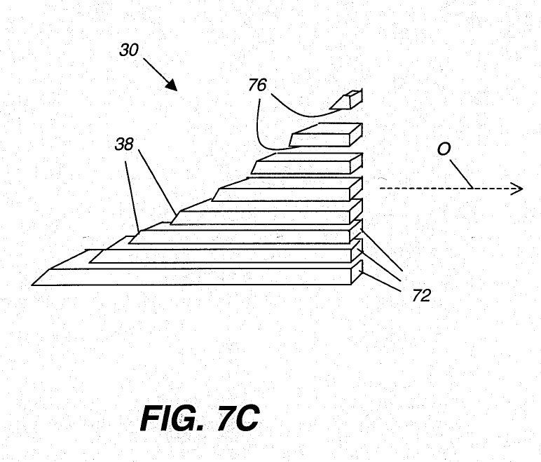

FIGS. 7A and 7B show side and orthogonal views, respectively, of an embodiment of illumination combiner apparatus 42 as an assembly with a composite light-redirecting prism 30 formed in this manner that combines laser light from four solid-state light arrays 44 . Since this combiner is fabricated from segmented glass pieces that are made in a conventional grind and polish method, there are no restrictions on the glass type that may be used. Therefore materials difficult to mold, such as fused silica, for example, can be used. Fused silica exhibits very little absorption, thus exhibiting negligible substrate heat up during operation. Alternatively, glass materials with a low coefficient of stress birefringence may be used, such as SF57, that only minimally create retardation upon either mechanical or thermal stress. Most of these latter type glasses are lead based and can be quite difficult to handle, therefore materials such as fused silica, provided with suitable coatings and low-absorption adhesives and using low-stress mounting with stable thermal environments, are advantaged for building this assembly. Formed from these materials, a segmented laser array combiner can handle optical densities of at least up to 6 W/cm² without significant degradation to the optical properties of light from the laser sources, which is well beyond the capability of a molded part.

Composite light-redirecting prism 30 has at least one incidence facet 32 that accepts light emitted from array 44 in an emission direction D1. Light is redirected to an output direction D2 that is parallel to output axis O and can be generally orthogonal to emission direction D1. Light redirecting prism 30, formed as described herein, has a plural number of light-redirecting facets 38. Each light-redirecting facet 38 is at an oblique angle relative to emission direction D1 and provides redirection, using a reflective coating or Total Internal Reflection (TIR), to incident light that is emitted from lasers 26. For example, light-redirecting facets 38 could be coated thin film structures or coated metal film. When staggered as shown in FIGS. 7A and 7B, these features help to narrow the light path for this illumination. As FIG. 7B shows, light arrays 44 have multiple lasers 26 that extend in a length direction L. Light-redirecting facets 38 and other facets also extend in direction L. The emission direction D1 for each of light arrays 44 is orthogonal (that is, perpendicular) to the length direction L. An output surface 34 then provides redirected light from the light arrays 44.

The perspective exploded view of FIG. 7C shows the components of light redirecting prism 30 as a composite prism structure in one embodiment. Composite light-redirecting prism 30 is formed as a stack of light-redirecting prisms 72. Each prism 72 has light-redirecting facet 38 for redirecting incident light in the direction of the optical axis O. Each prism 72 also has at least one contact surface 76 that is parallel to optical axis O and, in the assembled composite light-redirecting prism 30, is disposed in optical contact with an adjacent prism 72. Optical contact between neighboring prisms 72 can be effected using an optical adhesive or other intermediary material having a suitable index of refraction, for example, or by applying a holding pressure to the stack of prisms 72.

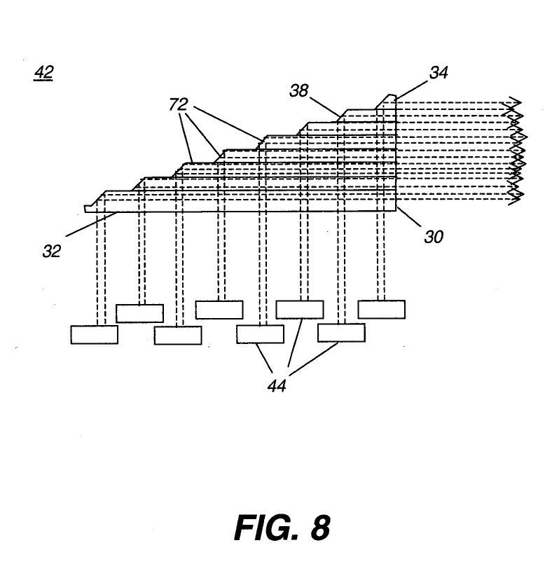

The cross-sectional side view of FIG. 8 shows an alternate embodiment using a stack of prisms 72, again with a single incidence facet 32 for light-redirecting prism 30 in illumination apparatus 42, in which light-redirecting facets 38 of light redirecting prism 30 are scaled so that each light-redirecting facet 38 redirects light from multiple rows of lasers 26 at a time.

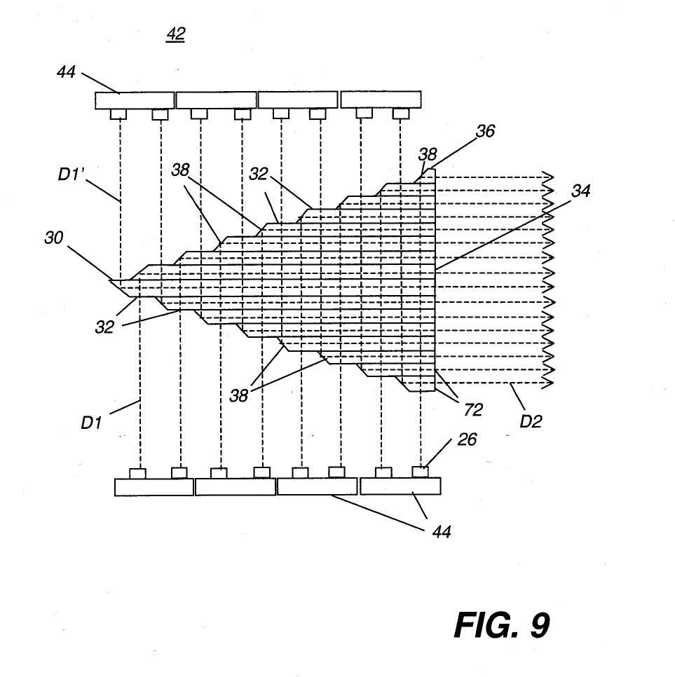

The cross-sectional side view of FIG. 9 shows another embodiment of illumination combiner apparatus 42 with light-redirecting prism 30 that provides even more compact arrangement of illumination components using solid-state arrays. Light redirecting prism 30 has two sides, each facing one or more solid-state light arrays 44. Light-redirecting facets 38 are staggered or offset so that light incident on the opposite side of light redirecting prism 30 is directed to an appropriate light-redirecting facet 38. In this arrangement, each side of composite light redirecting prism 30 has a plural number of incidence facets 32 and a plural number of light-redirecting facets 38. This allows light-redirecting prism 30 to accept light from arrays 44 that face each other, with generally opposing emission directions D1 and D1′. As noted with respect to FIG. 7B, the different emission directions D1 and D1′ for each of the respective light arrays 44 are both orthogonal with respect to the length direction for array 44 rows. Each side of composite prism 30, then, has these two types of facets: light-redirecting facets 38 and incidence facets 32 that can be normal or at a near-normal angle with respect to the incident light from the corresponding array 44. Light redirecting facets 38 on each side are in parallel. The paths of light from opposite sides of light redirecting prism 30 are interleaved within prism 30.

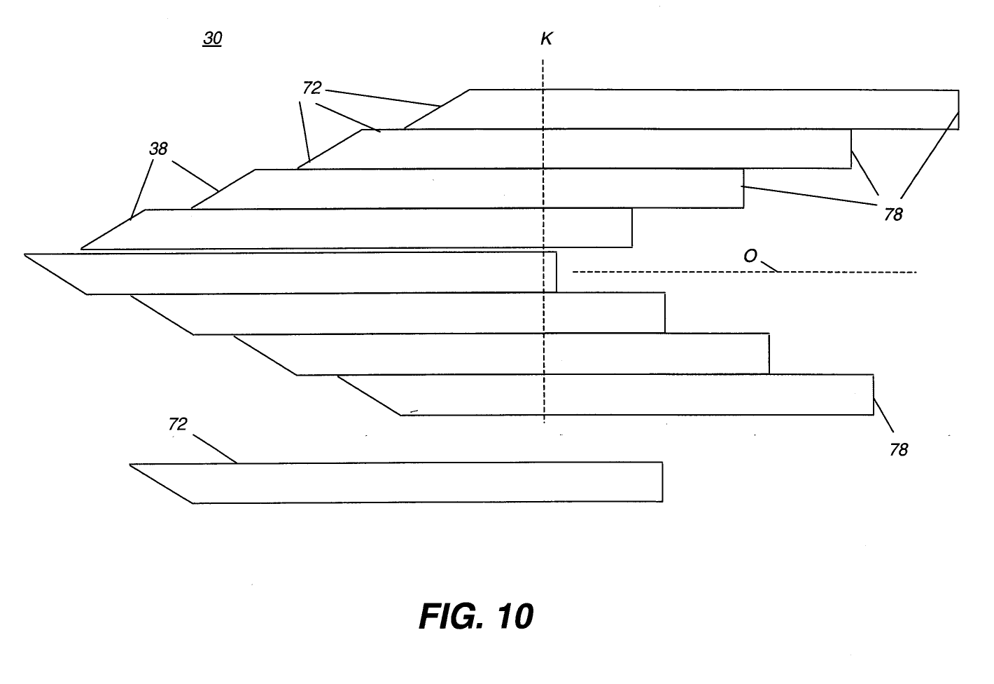

The side view of FIG. 10 shows an embodiment of composite light-redirecting prism 30 using a stack of prisms 72 that are disposed together with surfaces 76 in optical contact, wherein each prism 72 has the same dimensions. Here, since each prism 72 has an output surface 78, the effective output surface of composite light-redirecting prism 30 has multiple facets. Optionally, an assembled stack of prisms 72 can be cut at a line K so that the combined prisms 72 provide composite light-redirecting prism 30 with a planar output surface. While this embodiment shows the segments cut parallel to the output beams, it is possible to also fabricate segments that are substantially perpendicular to the light output beams.

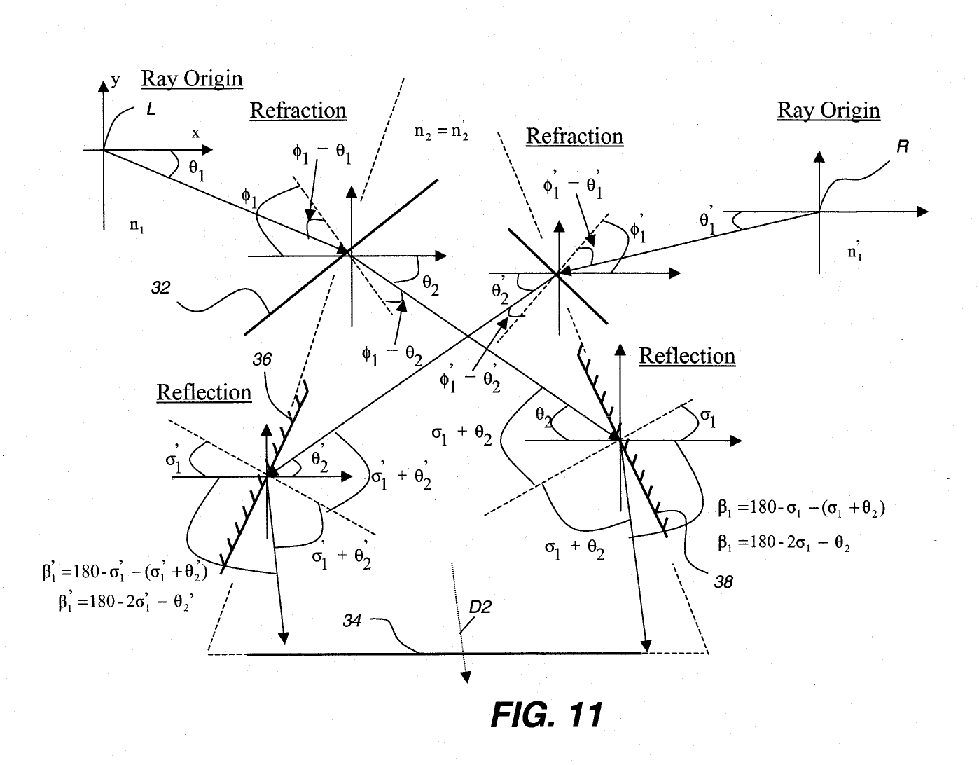

Segmented prism assemblies that combine and compact the light from laser arrays can be designed in many shapes and forms. In many instances, their compactness and symmetry are beneficial to the ease of alignment, design and fabrication simplicity, thus leading to a lower cost solution. FIG. 11 shows light handling considerations for light redirecting prism 30 in illumination combiner apparatus 42 for an application in which light enters from two sides in a symmetric fashion. Light redirecting facets 38 are offset to allow light incident on an opposite side of light redirecting prism 30 to be redirected. Using the reference coordinate system of FIG. 11, the lasers on opposite sides of prism 30 are offset in the vertical or Y direction. Similarly, the prism assemblies are also offset in this vertical direction by a corresponding amount. This offset symmetry enables left and right sided parts to be fabricated with either identical or mirrored assemblies and tooling. Likewise, the laser holders or mounts may be reused with identical or mirror parts, thus reducing setup times for the fabrication or assembly processes. This is particularly valuable in the process steps required in grinding and polishing of the optical facets.

Normal angular orientation allows for easier alignment of the various laser modules to composite light-redirecting prism 30 by retro-reflection of a small residual light from an anti-reflection coated face back into each of the lasers. This retro-reflection can be useful as a means of creating a subtle external cavity that may induce mode instability in the laser. While such mode hopping may be considered noise under typical applications, this noise can add value in projection applications by further reducing the laser coherence (and thus reducing inter-laser coherence) thereby reducing visual speckle at the image plane. Additionally, with this dual sided approach, laser modules are interleaved with light from different neighboring modules, providing a source of further spatial mixing when optically integrated further in the optical system. This again helps to reduce possible speckle and increase system uniformity.

While it can be seen that this normal orientation of incidence facets 32 of prism 30 to laser 44 is preferred, normal incidence light with respect to the incidence facets 32 or output surface 34 is not required for combining the illumination sources. It is required, however, that the light paths for light exiting prism 30 at surface(s) 34 be substantially parallel to each other. Obtaining parallel paths requires control of a number of factors, such as the following:

(i) the combination of the angle of incidence of the lasers 44 on each side (as they may be different) to input facets on each side;

(ii) the refraction in the prism 72 segments based on the index of refraction of the material;

(iii) the reflection from light redirecting facets 38 from each side (again these may be different on each side); and

(iv) the refraction for light exiting of prism 30.

These factors must cooperate so that output light paths from the exit face(s) are parallel.

FIG. 11 shows geometrical considerations for providing parallel output paths, with light parallel to output direction D2, when composite light redirecting prism 30 accepts light from two sides, as shown in the general arrangement of FIG. 9. In the particular example of FIG. 9, a simple embodiment is shown, with the incident light perpendicular at each incidence facet 32. FIG. 11 deals with the complexity of the more general case, in which incident light is at some oblique angle with respect to incidence facet 32. Refractive index n₁ or n₁′ is air or other surrounding medium. Refractive index n₂ or n₂′ is that of light redirecting prism 30.

Ray origin L is at left; ray origin R at right. A reference x-y coordinate axis is shown at these origins, at surfaces of incidence, and at surfaces at which light is reflected. Light from ray origin L is at an angle θ₁ relative to the reference coordinate system. Angle φ₁ is the normal to the incident surface of incidence facet 32. Refraction at facet 32 directs this light at angle θ₂ relative to the given x-axis. This light then reflects from redirection surface 38 that has a surface normal of σ₁. With respect to the x-axis, output direction D2 is at an angle β₁ from the x-axis where:

β₁=180−2σ₁−θ₂ (eq. 1)

The optical path from the right is similar. Light from ray origin R is at an angle θ₁′ relative to the reference coordinate system. Angle φ₁′ is normal to incidence facet 32. Refraction at facet 32 directs this light at angle θ₂′ relative to the given x-axis. This light then reflects from the surface that has a surface normal of σ₁′. With respect to the x-axis, output direction D2 is at an angle β₁′ from the x-axis where:

β′₁=180−2σ′₁−θ′₂ (eq. 2)

From FIG. 10 it can be seen that

β₁+β′₁=180 (eq. 3)

β₁=180−β′₁ (eq. 4)

So that

180−2σ₁−θ₂=180−(180−2σ′₁−θ′₂) (eq. 5)

180−2σ₁−θ₂=2σ′₁+θ′₂ (eq. 6)

Applying Snell's law for refracted light originating at ray origin L and incident from the left, using the notation for FIG. 10:

$$\begin{matrix}{n}_{1} sin ( {φ}_{1} - {θ}_{1} ) = {n}_{2} sin ( {φ}_{1} - {θ}_{2} ) & ( eq . 7 ) \\ sin ( {φ}_{1} - {θ}_{2} ) = \frac{{n}_{1}}{{n}_{2}} sin ( {φ}_{1} - {θ}_{1} ) & ( eq . 8 ) \\ ( {φ}_{1} - {θ}_{2} ) = {sin}^{- 1} ( \frac{{n}_{1}}{{n}_{2}} sin ( {φ}_{1} - {θ}_{1} ) ) & ( eq . 9 ) \\ {θ}_{2} = {φ}_{1} - {sin}^{- 1} ( \frac{{n}_{1}}{{n}_{2}} sin ( {φ}_{1} - {θ}_{1} ) ) & ( eq . 10 )\end{matrix}$$

Assuming that n₂=n₂′:

$${θ}_{2}^{′} = {φ}_{1}^{′} - {sin}^{- 1} ( \frac{{n}_{1}}{{n}_{2}} sin ( {φ}_{1}^{′} - {θ}_{1}^{′} ) ) \qquad ( eq . 11 )$$

Substituting from eq. 6:

$$180 - 2 {σ}_{1} - ( {φ}_{1} - {sin}^{- 1} ( \frac{{n}_{1}}{{n}_{2}} sin ( {φ}_{1} - {θ}_{1} ) ) ) = 2 {σ}_{1}^{′} + ( {φ}_{1}^{′} - {sin}^{- 1} ( \frac{{n}_{1}}{{n}_{2}} sin ( {φ}_{1}^{′} - {θ}_{1}^{′} ) ) ) \qquad ( eq . 12 )$$

Where eq. 12 is satisfied for the corresponding materials and angles, the output light that is redirected from light redirecting prism 30 will be in parallel for incident light from each side.

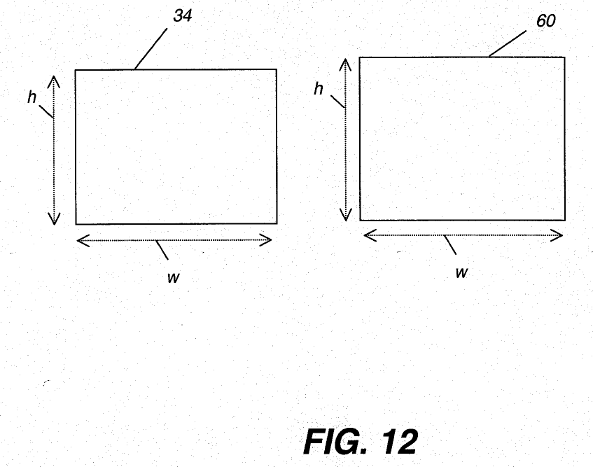

In a projector embodiment, such as shown in the schematic block diagram of FIG. 6, it is useful to substantially match the width:height aspect ratio of output surface 34 to the aspect ratio of its corresponding spatial light modulator 60. (As overfilling of the spatial light modulator is required, identical overfilling will result in a slight difference in aspect ratio.) This relationship is shown in FIG. 12 as w:h. As a rule-of-thumb, the w:h aspect ratio for output surface 34 should be within about ±0.3 of the aspect ratio for spatial light modulator 60. Light guide 52 (FIG. 6) or other waveguide element may also match the aspect ratio, while scaled to half size or other scaled dimensions.

Composite light directing prism 30 can be made from various types of highly transmissive materials for typical desktop and business projection applications. For these relatively low power applications, plastics may be chosen. It is preferred to use fabrication processes that induce very little stress to the part, particularly with plastics, to reduce birefringence. Similarly, it is desirable to choose materials that induce minimal stress or thermally induced birefringence. Plastics such as acrylic or Zeonex from Zeon Chemicals would be examples of suitable materials. This can be particularly important where the combiner is utilized in a polarization based optical system.

For higher power applications, such as for digital cinema projection where many high power lasers are required, plastics are impractical. Heat buildup from even small level of optical absorption could ultimately damage the material and degrade the light transmission. The light absorption in the material will also induce further stress birefringence that degrades the laser polarization states. For high lumen systems low absorption glass is preferred Glasses such as fused silica would absorb minimal light, thereby maintaining a stable temperature. This would prevent thermally induced stress birefringence from degrading the polarization states.

Alternatively to low absorption glasses, minimizing stress birefringence can be achieved by using a glass having low stress coefficients of birefringence, such as SF57. Where molding is desired, a slow mold process would be preferred, with annealing to reduce any inherent stress. A clean up polarizer may be desired or necessary to remove any rotated polarization states that might develop from residual birefringence. In general, however, these types of materials may not be conducive to creating such a molded glass component, thus requiring a more conventional polishing technique. This can be fabricated from a single piece of material or preferably an assembly of multiple segments to make up the completed prism as described earlier. The individual segments can be fabricated in plate form, with the sides polished for the input face and the end faces of the plates polished to the correct angles required. This method both simplifies the fabrication process and maintains the low stress required by high lumen systems.

As mentioned earlier, the segments of this combining prism could be non-identical. For example, if the segments are made with cuts parallel to the output face, the top most segment would be thinner than the bottom most segment. This approach may be advantaged from the standpoint of not fabricating pates that are long and thin, that may be difficult to assemble. In either case, utilizing segments, allow a conventional grind and polish operation to fabricate simple inexpensive parts that are assembled into a relatively complex, yet highly thermally stable prism combiner.

A number of improvements could be made to the basic prism 30 design shown in FIGS. 7A-9. For example, sides and output surface 34 of prism 30 could be antireflection coated or coated with spectrally rejecting thin film. Many of the lasers, such as the NESCEL's discussed earlier have residual light, often infrared, that must be rejected to prevent heating issues further in the system.

Embodiments of the present invention are useful for shaping the aspect ratio of the light source so that it suits the aspect ratio of the spatial light modulator that is used. Embodiments of the present invention can be used with waveguides of different dimensions, allowing the waveguide not only to be flexible, but also to be shaped with substantially the same aspect ratio to that of the modulator. For digital cinema this would be approximately 1.9:1.

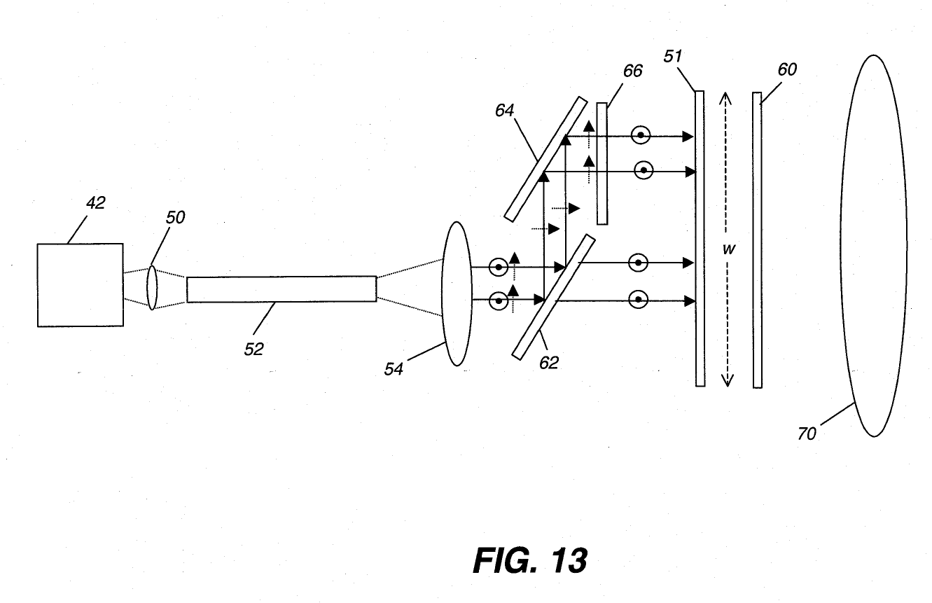

An alternative embodiment could use a square core fiber. In this case, the laser array would again be fabricated to match the aspect ratio of the square fiber. The methods utilized in earlier embodiments along with the optional use of polarization combining would work similarly. On the output side, the square aspect ratio would not appropriately match the modulator aspect ratio. In this case, however, there might be the desire to use a polarized illumination such as required by an LCOS spatial light modulator. Referring to the schematic diagram of FIG. 13, there is shown an embodiment of a light modulation assembly 40 that provides polarized light and uses a polarization recovery technique to adapt the illumination aspect ratio to the aspect ratio of its spatial light modulator 60. Here, light guide 52 has an aspect ratio that is approximately half of the aspect ratio of spatial light modulator 60. The illumination that is output from light guide 52 and is directed through lens 54 is substantially unpolarized. Conventional dot and arrow notation is used in FIG. 13 to designate polarization states. A first polarization beamsplitter 62 transmits s-polarized light and reflects p-polarized light toward a second polarization beamsplitter 64. Polarization beamsplitter 64 reflects the p-polarized light through a half-waveplate 66 that changes the polarization state to s-polarized light. In this way, the illumination that is incident on integrator 51 and goes to spatial light modulator 60 is highly polarized. Moreover, the aspect ratio of this illumination is increased in the width w direction, as indicated in FIG. 13. This arrangement effectively doubles the area of the light source to provide improved aspect ratio matching and provides a uniform, polarized light that is particularly suitable for LCOS devices.

Similarly, a round core optical waveguide, such as common multimode optical fiber can be utilized. In this case, the laser source array could be square as discussed in the prior embodiment. To make best use of this laser array, however, the array source must be focused down to a smaller size than that of the optical fiber core. This means that the angle of the light entering the waveguide is increased. Thus some etendue loss is associated with this mismatch in shape. This mismatch may be reduced, however, if the laser array could be rounded by the use of shorter laser arrays with fewer active elements, (improving the effective laser device yield by allowing usage of shorter cut arrays), combined on the edges of the square array to “round out” the effective source. While this would provide a higher brightness, some etendue loss will occur on the modulator side when the output is uniformized and matched to the rectangular shape of the modulation device.

A fiber optical waveguide, being multi-mode, will not preserve the inherent polarization of the lasers. Therefore, a device such as a DLP modulator can directly use the unpolarized light, after uniformizing, mixing, or optically integrating, such as using an integrating bar or lenslet array.

While an optical waveguide between the illumination combiner apparatus 42 and integrator 51 is the embodiment shown for light guide 52, other methods for relaying and separating the illumination sources from the projection optical engine are possible. Relaying with standard lenses would be another approach for achieving the desired thermal and spatial separation.

The invention has been described in detail with particular reference to certain preferred embodiments thereof, but it will be understood that variations and modifications can be effected within the spirit and scope of the invention. For example, where laser arrays are described in the detailed embodiments, other solid-state emissive components could be used as an alternative. Supporting lenses and other optical components may also be added to each optical path.

Thus, what is provided is an apparatus and method using solid-state array illumination for digital cinema projection.

The invention has been described with reference to a preferred embodiment. However, it will be appreciated that variations and modifications can be effected by a person of ordinary skill in the art without departing from the scope of the invention.

### PARTS LIST

10. Projector apparatus
12. Light source
14. Prism assembly
18. Optics
20, 20r, 20g, 20b. Spatial light modulator
26. Laser
30. Light redirecting prism
32. Incidence facet
34. Output surface
38. Light-redirecting facet
40, 40r, 40g, 40b. Light modulation assembly
42. Illumination combiner apparatus
44, 44′. Solid-state light array
46. Mirror
48, 56. Polarization beamsplitter
50. Lens
51. Integrator
52. Light guide
54. Lens
60. Spatial light modulator
62, 64. Polarization beamsplitter
66. Waveplate
70. Projection optics
72. Prism
76. Surface
78. Surface
80. Display surface
D1, D1′. Emission direction
D2. Output direction
L. Ray origin
R. Ray origin
h. Height
w. Width

1. An illumination apparatus for a digital image projector, the illumination apparatus comprising:
a) a plurality of solid-state laser arrays, each laser array comprising one or more rows of lasers; and
b) a light combiner having an output optical axis and comprising a plurality of light-redirecting prisms arranged in a stack, each light-redirecting prism comprising:
(i) at least one contact surface that extends parallel or substantially parallel to the output optical axis and is in optical contact with an adjacent prism in the stack; and
(ii) a light redirecting facet that is disposed at an oblique angle to the at least one contact surface.

2. The illumination apparatus of claim 1 wherein each light-redirecting prism has an output surface that is substantially orthogonal to its at least one contact surface.

3. The illumination apparatus of claim 1 wherein the lasers are vertical-cavity devices.

4. The illumination apparatus of claim 1 wherein the light-redirecting facets provide total internal reflection for incident light.

5. The illumination apparatus of claim 1 wherein at least one light-redirecting facet is a coated thin film structure.

6. The illumination apparatus of claim 1 wherein at least one light-redirecting facet is a coated metal film.

7. The illumination apparatus of claim 2 further comprising a coating on at least one of the at least one light redirecting facet and the output surface.

8. The illumination apparatus of claim 7 wherein the coating is taken from the group consisting of an antireflection coating and an IR rejection coating.

9. The illumination apparatus of claim 1 further comprising a spatial light modulator in the path of light from the output surface.

10. The illumination apparatus of claim 9 wherein the output surface has an aspect ratio that is within ±0.3 of the aspect ratio of the spatial light modulator.

11. The illumination apparatus of claim 2 further comprising a waveguide for directing light from the output surface.

12. The illumination apparatus of claim 2 further comprising an optical integrator for receiving light from the output surface.

13. The illumination apparatus of claim 11 wherein the waveguide is an optical fiber.

14. The projection apparatus of claim 9 wherein the spatial light modulator is taken from the group consisting of a digital micromirror device and a liquid-crystal-on-silicon device.

15. The projection apparatus of claim 2 further comprising at least one polarization beamsplitter in the path of the redirected light from the output surface.

16. The projection apparatus of claim 15 further comprising a half-wave plate in the path of light that is redirected through the at least one polarization beamsplitter.

17. An illumination apparatus for a digital image projector, the illumination apparatus comprising:
a) a plurality of solid-state laser arrays, each laser array comprising one or more rows of lasers; and
b) a light combiner having an output optical axis and comprising a plurality of light-redirecting prisms arranged in a stack, each light-redirecting prism comprising:
i) at least one contact surface that extends perpendicular or substantially perpendicular to the output optical axis and is in optical contact with an adjacent prism in the stack; and
ii) a light redirecting facet that is disposed at an oblique angle to the at least one contact surface.

18. The illumination apparatus of claim 17 wherein each light-redirecting prism has an output surface that is substantially perpendicular to its at least one contact surface.

19. An illumination apparatus for a digital image projector, the illumination apparatus comprising:
a plurality of solid-state laser arrays, each laser array comprising one or more rows of lasers, the rows extending in a length direction, and each laser in the laser arrays disposed to direct light in an emission direction that is orthogonal to the length direction; and
a light-redirecting prism comprising a plurality of incidence facets disposed on two sides of the light-redirecting prism and wherein the plurality of light-redirecting facets are also disposed on the same two sides of the light-redirecting prism.

20. The illumination apparatus as described in claim 19 wherein the pattern of incident facets and light redirecting facets from opposing sides forms an offset symmetry.
